(19) United States
(12) Patent Application Publication
(10) Pub. No.: US 2010/0097836 A1
(43) Pub. Date: Apr. 22, 2010

(54) Memory Bitcell and Method of Using the Same

(76) Inventor: Charles Smith, Cambridge (GB)

Correspondence Address: Roland Tso;Cavendish Kinetics Patent Dept., 3833 North First Street, San Jose, CA, 95134, US

(21) Appl. No.: 11/989,878

(22) PCT Filed: Aug. 3, 2006
(86) PCT No.: PCT/GB2006/002892

§ 371 Date: Feb. 1, 2008

(30) Foreign Application Priority Data
Aug. 3, 2005 (GB) 0515980.1

(51) Int. Cl. G11C 17/00

(52) U.S. Cl. 365/104

(57) ABSTRACT

A memory bitcell comprises first (102) and second (103) transistors and a cantilever module (104) having two states. The first transistor (102) is arranged to communicate a first signal to the input of the cantilever module (104) upon receipt of a second signal. The second transistor (103) is arranged to bypass the cantilever module (104) upon receipt of a third signal (RST). The memory bitcell is operable such that the state of the cantilever (104) can be changed in order to represent one bit of binary information and can be detected by monitoring the first signal.

The present invention relates to the field of one time programmable memory bitcells. The present invention provides a simple and cost effective solution to the problem of complex and bulky one time programmable memory bitcells.

Many prior art one time programmable bitcells comprise a large number of components. This increases the size of the resulting memory arrays and also adds to the complexity of both the programming and reading of the bitcells. Also, such bitcellscan be costly to manufacture.

Thus, there is a dear need for a simple and cost effective one time programmable memory bitcell.

In order to solve the problems associated with the prior art, the present invention provides a memory bitcell which comprises:

first and second transistors; and

a cantilever module having two states,

wherein the first transistor is arranged to communicate a first signal to the input of the cantilever module upon receipt of a second signal and the second transistor is arranged to bypass the cantilever module upon receipt of a third signal, such that the state of the cantilever can be changed in order to represent one bit of binary information and can be detected by monitoring the first signal.

Preferably, the gate of the first transistor is connected to a wordline;

the source of the first transistor is connected to a bitline,

the drain of the first transistor is connected to both a first terminal of the cantilever module and the the source of the second transistor; and

the drain of the second transistor is connected to a second terminal of the cantilever module.

Preferably, the memory bitcell further comprises:

a charging transistor arranged to communicate the first signal to the first transistor.

The present invention also provides a memory array which comprises:

a plurality of memory bitcells according to any of the preceding claims.

There are several advantages to which are provided by the present invention. The circuit of the present invention is simple and therefore has fewer parts to manufacture, diminishing the complexity of driver circuits as well as the size, complexity and manufacturing costs of bitcell arrays.

An example of the present invention will now be described with reference to the accompanying drawings, in which:

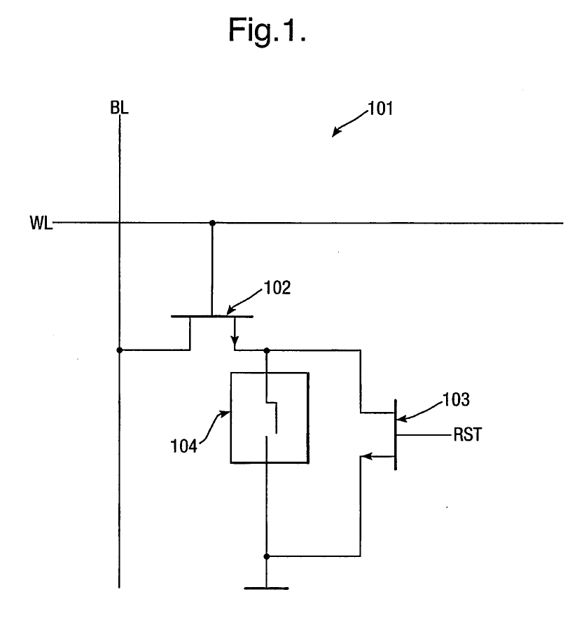

FIG. 1 shows a schematic diagram of a 2-transistor cantilever bitcell in accordance with one example of the present invention;

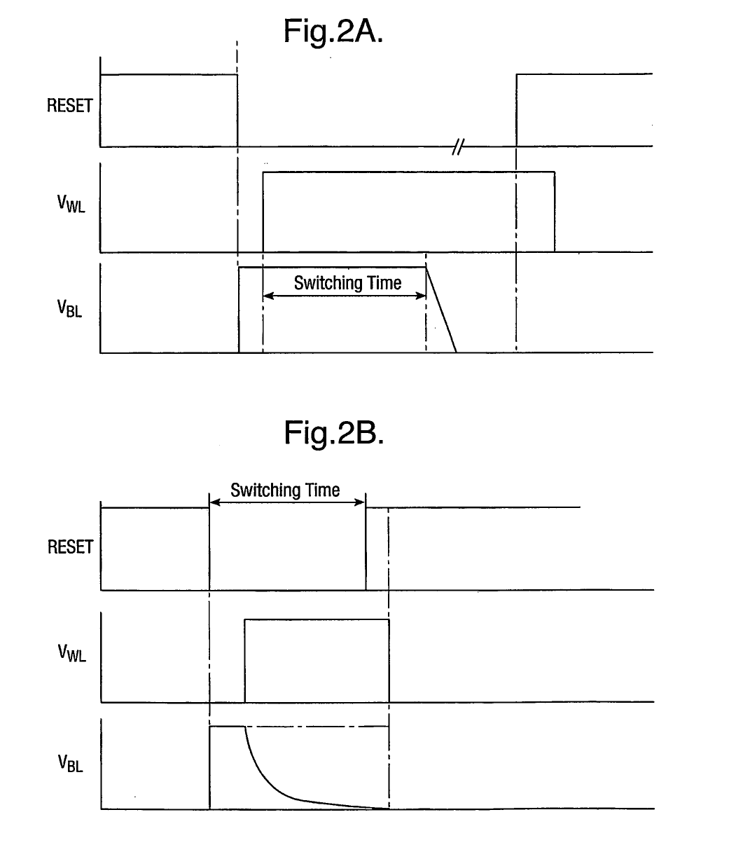

FIG. 2A shows a timing diagram of the control signals which are needed during the programming cycle of the 2-transistor cantilever bitcell of FIG. 1;

FIG. 2B shows a timing diagram of the control signals which are needed during the read cycle of the 2-transistor cantilever bitcell of FIG. 1;

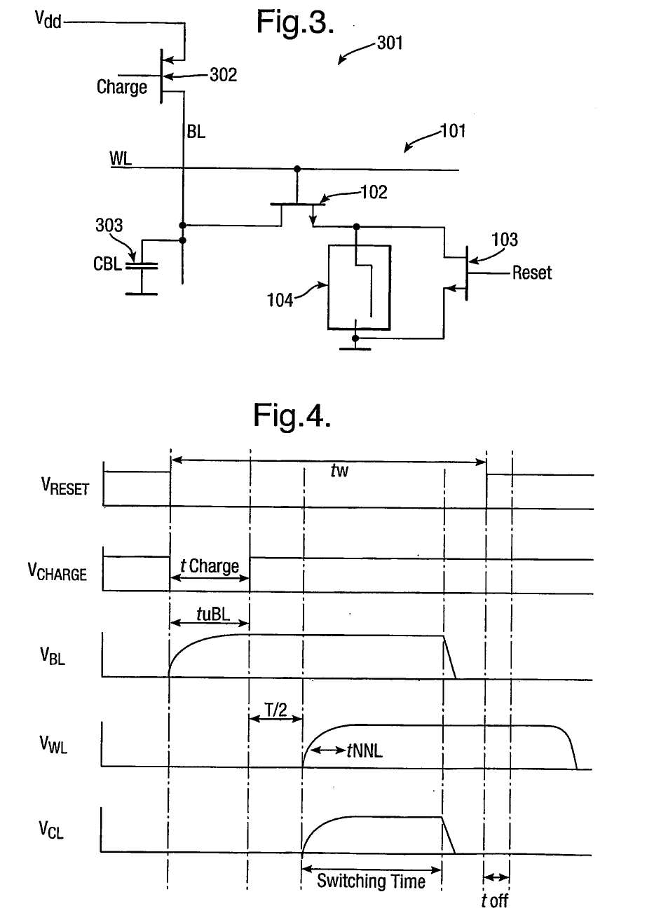

FIG. 3 shows a schematic diagram of a 2-transistor cantilever bitcell in accordance with a another embodiment of the present invention;

FIG. 4 shows a detailed timing diagram of the programming operation of the 2-transistor cantilever bitcell of FIG. 3;

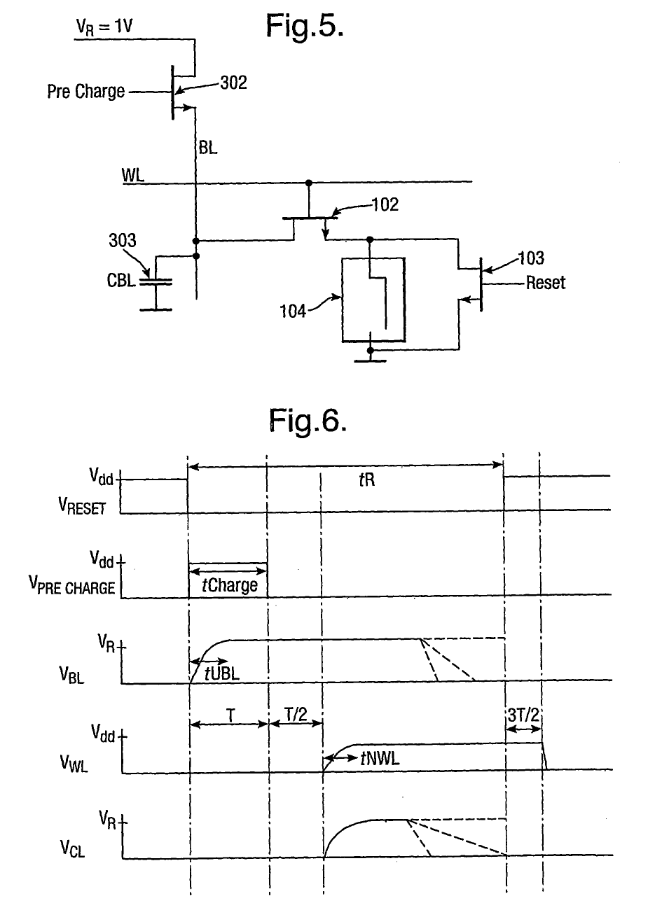

FIG. 5 shows a schematic diagram of a 2-transistor cantilever bitcell in accordance with another embodiment of the present invention;

FIG. 6 shows a detailed timing diagram of the programming operation of the 2-transistor cantilever bitcell of FIG. 5;

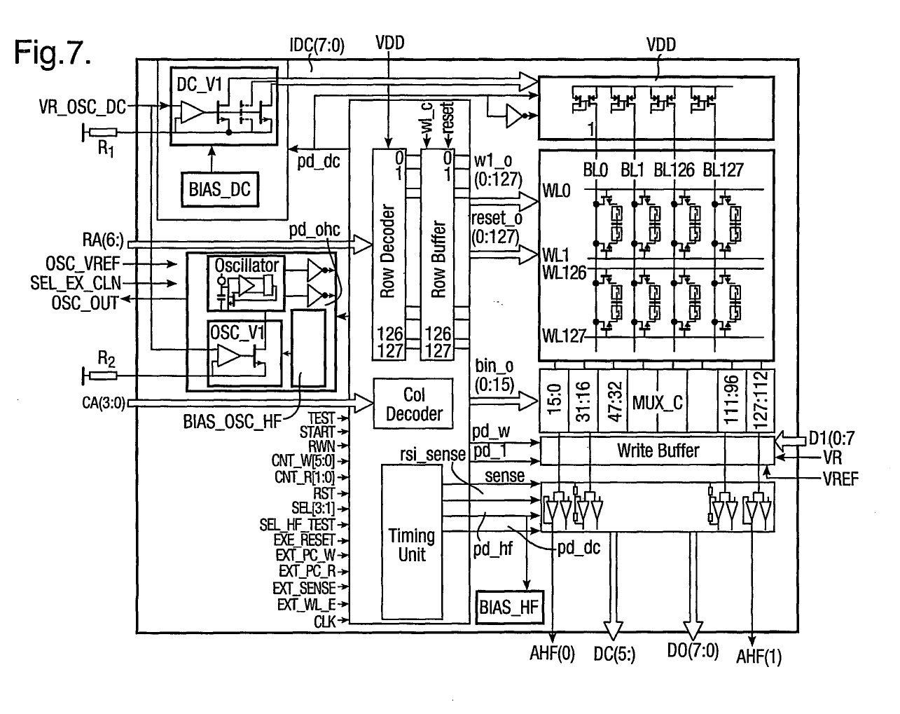

FIG. 7 shows a high-level schematic diagram of an OTP memory architecture in accordance with one embodiment of the present invention; and

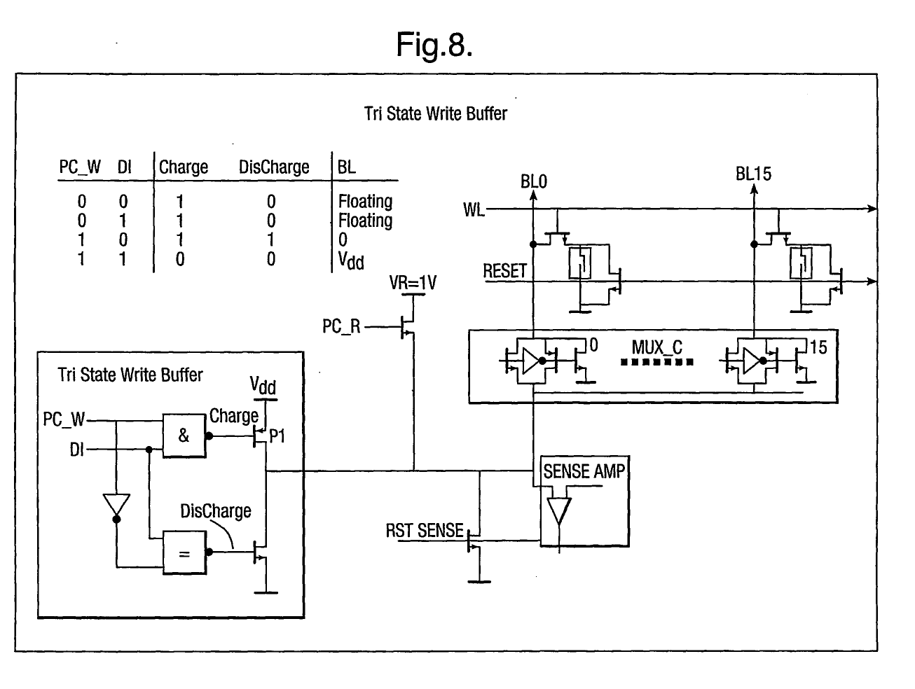

FIG. 8 shows the interface between the write buffer and the sense amp of FIG. 7.

In reference to FIG. 1, a memory bitcell 101 in accordance with one example of the present invention comprises a first transistor 102, a second transistor 103 and a cantilever unit 104. The gate of the first transistor 102 is connected to the wordline (WL) of a control circuit (not shown), the source of the first transistor 102 is connected to the Bit Line of the control circuit and the drain of the first transistor 102 is connected to a first end of the cantilever unit 104 as well as the source of the second transistor 103. The gate of the second transistor 103 is connected to a Reset (RST) input signal line of the control circuit and the drain of the second transistor 103 is connected to a second end of the cantilever unit 104.

Now with reference to FIG. 2A and 2B, the operation of the circuit shown in FIG. 1 will now be described. The first operation which will be described is that of programming the bitcell.

The bitcell is programmed by setting the RESET input signal to ground, thereby switching the second transistor 103 off. Next, the bitline is charged to Vdd. The rising edge of the bitline is allowed to coincide with the falling edge of the RESET input signal, assuming that the V_{WL} is low. The rise time of the bitline (t_{rBL}) depends on the parasitic capacitance of the bitline (C_{BL}) and the dimensions of the specifications of the pre-charge transistor 302.

$${β}_{transistor 1} = \frac{2 \cdot {C}_{BL}}{{V}_{dd} \cdot {t}_{rBL}}$$

For example, if C_{BL}=2 pF, V_{dd}=8V and t_{rBL}=5 ns then βₜᵣₐₙₛᵢₛₜₒᵣ₁=100 μA/V². It is known that a p-channel transistor with W=10 μm and L=0.5 μm has a β of at least 100 μA/V². Thus, if a transistor was constructed with a W=7.2 μm and a L=0.6 μm, then the corresponding rise time would be less than 5 ns for a supply voltage range from 2V to 8V. The charge transistor 302 is switched off after the bitline is charged to V_{dd} (t_{charge}>t_{rBL}). At this point, the bitline will be floating.

Next, the voltage at the Bitline is transferred to the cantilever module 104 by setting the gate voltage of the first transistor (wordline) high. The voltage across the cantilever (V_{CL}) depends on the voltages at the bitline and wordline.

For example, if V_{WL}=V_{dd}, then V_{CL}=V_{dd}−V_{T}, where V_{T} is the threshold voltage across the first NMOS transistor 102 and V_{CL} is the voltage across the cantilever module 104. In this case, the cantilever voltage is lower than the V_{dd} and is a function of V_{T}, which itself depends on the temperature, process variations and source to substrate voltage. The V_{T} is around 1V because of the body effect of the first transistor 102. Also, the source to substrate voltage is not 0. Alternatively, if V_{BL}<V_{WL}−V_{T}, then V_{CL}=V_{BL}.

The wordline voltage should remain high during the rest of the programming cycle. The cantilever needs a certain time before it pulls in. The switching time is defined as the time needed until the cantilever pulls in. The switching time depends on the applied voltage across the cantilever, the length of the cantilever and the curvature of the cantilever.

The RESET signal should be kept LOW longer than the switching time. Because the switching time is not known beforehand, the duration of the RESET signal (t_{W}) should be programmable externally. Also, the supply voltage is variable externally. Thus, the write operation takes at least (t_{charge}+Switching time).

Now, with reference to FIGS. 5 and 6, an example of the read operation will now be described. First, the second transistor 103 is switched off. Then, the bitline is pre-charged to V_{R}. V_{R} is preferably a low voltage. Otherwise, there is a risk that the cantilever can be programmed accidentally or even damaged. The lower value of V_{R} is set by a sense amplifier (not shown). Thus, V_{R} should be in the operating range of the sense amplifier. After the bitline is pre-charged, it is set to floating by switching off the pre-charge transistor 302. Because the pre-charge transistor 302 operates in the linear region, it can be represented by a resistor, as per the following equation.

$${R}_{pre \text{-} charge \text{-} transistor} = \frac{1}{{β}_{N 3} \cdot ( {V}_{GS 3} - {V}_{T} )}$$

In the following example, it can be assumed that the t_{rBL}=3 T=3 ns, that T=1 ns=R_{N3}*C_{BL} and that R_{N3}=1 ns/2 pF=500Ω. Thus, in this example, it can be shown that:

$${β}_{pre \text{-} chrage \text{-} transistor} = \frac{1}{500 \cdot ( 4 - 0.7 )} = 606 \frac{µA}{{V}^{2}}$$

It is known that an NMOS transistor with W=10 μm and L=0.5 μm has a β of at least 2253 μA/V². For the following example, a transistor with W=5 μm and L=0.6 μm will be considered.

Next in the read operation is the step of switching the first transistor 102. This is done by setting the wordline to HIGH (V_{dd}). During this time, the charge on the bitline is transferred to the cantilever. Depending on the state of the cantilever, two situations can arise.

In the situation where the cantilever is not programmed, the cantilever module 104 will have a very high resistance. Also, the voltage at the bitline will remain HIGH because the parasitic capacitance of the cantilever is much lower (10 fF) than the parasitic capacitance of the bitline (2 pF). This phenomenon is represented in FIG. 6 by the dashed lines.

in the situation where the cantilever is programmed, the cantilever module 104 will have a low resistance. In this case, the bitline will be discharged by the resistor of the cantilever (R_{CL}) according to the following function.

V_{BL}=1^{-1/r}

The time constant Tis equal to R_{CL}*C_{BL} with R_{CL}=10 kΩ and C_{BL}=2pF. Therefore, T=20 ns. The voltage at the bitline is 0.367V (1V/2.7) after 1 T and is 0.9V after 0.1 T. This means that the bitline voltage is reduced by 100 mV after 2 ns. If the threshold level of the sense amplifier is set to 100 mV, activation of the sense amplifier must be delayed by a further 2 ns once the first transistor 102 has been switched on.

Finally, with reference to FIG. 7, a high level circuit of the OTP will be shown. The column address is generated from one 4 bit long external address bus CA(3:0). The Col Decoder converts the 4 bit address information into a 16 bit Col Address. The MUX_C is driven by a 16 bit long column address. The 128 columns are divided in 8 blocks, each of 16 bits. The 16 bit long address contains only one high bit. The other bits are zero. Thus, in each block, the same bit can be selected by making the corresponding address bit high. For example, in order to select position 3 in each block, the third bit of the address would need to be pulled HIGH while the other bits of the address would be LOW. Each block of the MUX_C is connected to one sense amp.

1. A memory bitcell comprising:
first and second transistors; and
a cantilever module having two states, wherein the first transistor is arranged to communicate a first signal to an input of the cantilever module upon receipt of a second signal and the second transistor is arranged to bypass the cantilever module upon receipt of a third signal, such that the state of the cantilever module can be changed in order to represent one bit of binary information and can be detected by monitoring the first signal.

2. The memory bitcell according to claim 1, wherein:
a gate of the first transistor is connected to a wordline;
a source of the first transistor is connected to a bitline;
a drain of the first transistor is connected to both a first terminal of the cantilever module and a source of the second transistor; and
a drain of the second transistor is connected to a second terminal of the cantilever module.

3. (canceled)

4. (canceled)

5. A memory bitcell comprising:
a first MOS transistor having a drain terminal, a gate terminal, and a source terminal, the gate terminal of the first MOS transistor is configured to receive a first control signal, and wherein the first control signal is used to turn ON the first MOS transistor;
a second MOS transistor having a drain terminal, a gate terminal, and a source terminal, wherein the drain terminal of the second MOS transistor is connected to the source terminal of the first MOS transistor, and the gate terminal of the second MOS transistor is configured to receive a second control signal, wherein the second control signal is used to turn ON the second MOS transistor; and
a cantilever module having two states, and wherein the cantilever module includes a first terminal and a second terminal, and wherein the first terminal is connected to the source terminal of the first MOS transistor, and the second terminal is connected to the source terminal of the second MOS transistor.

6. The memory bitcell of claim 5 wherein the first and second MOS transistors are N-channel MOS transistors.

7. The memory bitcell of claim 1, further comprising:
a charging transistor configured to communicate the first signal to the first transistor.

8. The memory bitcell of claim 5, further comprising:
a charging MOS transistor having a drain terminal, a gate terminal, and a source terminal, wherein the source terminal of the charging MOS transistor is connected to the drain terminal of the first MOS transistor, the drain terminal of the charging MOS transistor is configured to receive a first signal, and the gate terminal of the charging MOS transistor is configured to receive a third control signal, wherein the third control signal is used to turn on the charging MOS transistor to communicate the first signal to the drain terminal of the first MOS transistor.

9. A memory array having a plurality of memory bitcells, each memory bitcell comprising:
first and second transistors;
a cantilever module having two states, wherein the first transistor is arranged to communicate a first signal to an input of the cantilever module upon receipt of a second signal and the second transistor is arranged to bypass the cantilever module upon receipt of a third signal, such that a state of the cantilever can be changed in order to represent one bit of binary information and can be detected by monitoring the first signal;
wherein the gate of the first transistor is connected to a wordline, the source of the first transistor is connected to a bitline, the drain of the first transistor is connected to both a first terminal of the cantilever module and the source of the second transistor, and the drain of the second transistor is connected to a second terminal of the cantilever module.

10. The memory array of claim 9, wherein the first and second transistors are N-channel MOS transistors.

11. The memory array of claim 9, wherein each memory bitcell further comprises a charging transistor arranged to communicate the first signal to the first transistor.
